(19) United States
(12) Patent Application Publication
(10) Pub. No.: US 2021/0167336 A1
(43) Pub. Date: Jun. 3, 2021

(54) HEATING DEVICE

(71) Applicant: BOE TECHNOLOGY GROUP CO., LTD., Beijing (CN)

(72) Inventors: Bin ZHOU, Beijing (CN); Guangcai YUAN, Beijing (CN); Dongfang WANG, Beijing (CN); Ce ZHAO, Beijing (CN); Jun CHENG, Beijing (CN); Luke DING, Beijing (CN)

(21) Appl. No.: 15/780,359

(22) PCT Filed: Nov. 8, 2017
(86) PCT No.: PCT/CN2017/109910

§ 371 Date: May 31, 2018

(30) Foreign Application Priority Data
Apr. 28, 2017 (CN) 201720473032.2

(51) Int. Cl. H01L 51/56; H05B 1/02; F28F 3/12; H05B 3/22

(52) U.S. Cl. CPC H01L 51/56; H05B 1/0233; H01L 27/322; H05B 3/22; F28F 3/12

(57) ABSTRACT

The present disclosure provides a heating device for heating an OLED substrate, comprising: a heating plate, a support, and a temperature controller, the temperature controller is connected with the heating plate and the support respectively, and the temperature controller is used to synchronously heat the heating plate and the support, so that the temperature of the heating plate and the support are substantially the same; wherein the heating plate comprises an receiving portion for accommodating the support, the support is configured to be able to protrude from the heating plate and retract into the heating plate.

### CROSS-REFERENCE TO RELATED APPLICATION

This is a National Phase Application filed under 35 U.S.C. 371 as a national stage of PCT/CN2017/109910, filed on Nov. 8, 2017, an application claiming the benefit of Chinese Application No. 201720473032.2, filed in China on Apr. 28, 2017, the entire contents of which are hereby incorporated by reference.

### TECHNICAL FIELD

The present disclosure relates to the field of display technology, and in particular to a heating device.

### BACKGROUND

In the manufacturing process of COA (Color Filter On Array) substrate, it is necessary to perform heat curing to the substrate coated with an organic material. For example, the substrate is placed on a heating plate. The organic material is coated on the surface of the substrate; heat is transferred to the substrate through the heating plate, so that the organic material on the surface of the substrate is cured to form an organic filter layer, or is formed an organic light emitting layer in organic electroluminescent devices. However, there are some mura on the organic filter layer or the organic light emitting layer.

### SUMMARY

The present disclosure at least relates to a heating device for heating an OLED substrate, comprising: a heating plate, a support, and a temperature controller, the temperature controller is connected with the heating plate and the support respectively, and the temperature controller is used to synchronously heat the heating plate and the support, so that the temperature of the heating plate and the support are substantially the same; wherein the heating plate comprises an receiving portion for accommodating the support, the support is configured to be able to protrude from the heating plate and retract into the heating plate.

Optionally, the temperature controller comprises a monitor and a heating member, the heating member configured to heat the heating plate and the support, the monitor is configured to monitor a temperature of the heating plate and the support, the monitor is connected with the heating plate and the support, respectively.

Optionally, the temperature controller further comprises a cooling member, and the heating plate and the support are provided with the cooling member.

Optionally, the support and the heating plate comprises a heat conductive material.

Optionally, the support or the heating plate comprises a heat conductive material.

Optionally, the heat conductive material comprises a metal material.

Optionally, the heat conductive material is stainless steel or aluminum alloy.

Optionally, the support is a supporting pin.

Optionally, the heating member is a heating wire.

Optionally, the heating wire is inside the heating plate and the support.

Optionally, the cooling member is a cooling water pipeline.

Optionally, the temperature controller further comprises a programmable logic controller, the programmable logic controller is used to control conduction or disconnection to the heating member and cooling member according to a control program stored in advance in the programmable logic controller when the monitor monitors that the temperature of the heating plate and the support reach a predetermined temperature.

Optionally, the temperature controller further comprises a programmable logic controller, the programmable logic controller is used to control conduction or disconnection to the heating member or cooling member according to a control program stored in advance in the programmable logic controller when the monitor monitors that the temperature of the heating plate and the support reach a predetermined temperature.

### BRIEF DESCRIPTION OF THE DRAWINGS

FIG. 1 is a schematic structural view of a heating device provided in an embodiment of the present disclosure;

FIG. 2 is a schematic view of a support protruding from a heating plate for carrying an object to be cured in an embodiment of the present disclosure;

FIG. 3 is a schematic view of a support retracting into a heating plate for placing an object to be cured in an embodiment of the present disclosure.

### DETAILED DESCRIPTION OF THE EMBODIMENTS

To enable those skilled in the art to better understand the technical solutions of the present disclosure, a heating device provided in the present disclosure will be described in detail below in conjunction with the accompanying drawings.

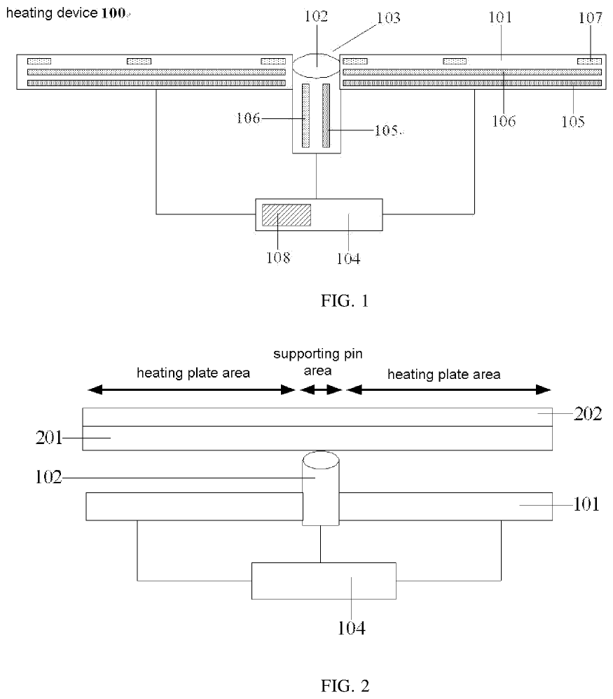

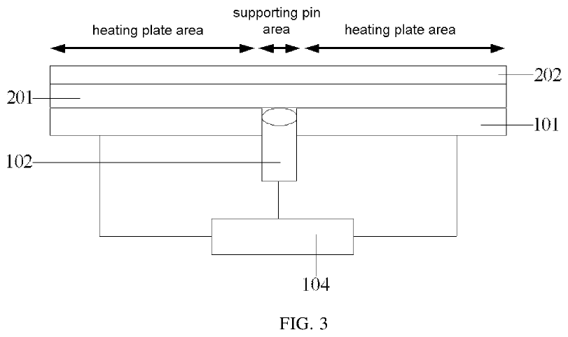

FIG. 1 is a schematic structural view of a heating device 100 according to an embodiment of the present disclosure. As shown in FIG. 1, the heating device 100 comprises a heating plate 101, a support 102, and a temperature controller 104. The substrate is placed on the heating plate and the support (supporting pin). The heating plate 101 comprises a receiving portion 103 for accommodating the supporting 102. The support 102 is configured to be movable in the receiving portion 103. As shown in FIG. 2 and FIG. 3, the support 102 can protrude from the heating plate 101 and retract into the heating plate 101. The heating plate 101 is used to perform heat treatment to an object to be cured. The support 102 is used to support the object to be cured when it protrudes from the heating plate 101, and to place the object to be cured on the heating plate to prepare for curing when the support 102 retracts into the heating plate 101. The temperature controller 104 is connected with the heating plate 101 and the support 102, respectively. The temperature controller 104 is used to synchronously heat the heating plate 101 and the support 102, so that the temperature of the heating plate 101 and the support 102 are substantially the same. Those ordinary skilled in the art will understand that substantially the same temperature herein means that the temperature difference between the two is in the range of ±2° C. The heating plate 101 and the support 102 provided in this embodiment have substantially the same temperature, which improves the temperature difference of the object to be cured at positions corresponding to areas of the heating plate and the support. The evaporation uniformity of the solvent of a film layer is improved, and the uniformity of the thickness of film layer after the heat curing is improved. In other words, the case that the display panel corresponding to an area of the heating plate and the supporting pin is not heated uniformly, evaporation of the reagent on the surface of the display substrate is non-uniform, resulting in defects such as uneven thickness of pin-shaped film (Pin Mura) might be prevented.

In this embodiment, a material forming the support and/or the heating plate comprises a heat conductive material. The support is a supporting pin. In this way, the temperature difference of the substrate to be heated at positions corresponding to areas of the heating plate and the supporting pin is most likely minimized. Thereby further reducing the temperature difference of an object to be cured, such as an organic film layer on the heating substrate. It can be understood that the organic film layer here is formed on the substrate. The evaporation uniformity of the solvent of a film layer is improved, and the uniformity of the thickness of film layer after a subsequent heat curing is further improved. The unevenness of the thickness of the pin-shaped film is reduced (i.e., incidence of Pin Mura is reduced), and the product yield and productivity is increased. Optionally, the heat conductive material comprises a metal material. Further, the heat conductive material may be stainless steel or aluminum alloy. Optionally, the same material as the support can be selected for the heating plate. This minimizes the temperature difference between the heating plate and the support. The heat conductive material provided in this embodiment can ensure that the temperature difference between the heating plate 101 and the support 102 is as small as possible. Thereby improving the temperature difference between areas of the heating plate and the supporting pin, and improving the uniformity of the thickness of the film after the heat curing.

Referring to FIG. 1, the temperature controller 104 comprises a monitor 107 and a heating member provided at respective positions of the heating plate 101 and the support 102. That is, the heating member is configured to heat the heating plate 101 and the support 102. The monitor is used to monitor the temperature of the heating plate 101 and the support 102, and the monitor is connected to the heating plate 101 and the support 102, respectively. Optionally, the monitor 107 may be a temperature sensor. The heating member may be a heating wire 105. The heating wire 105 is distributed inside the heating plate 101 and the support 102. Optionally, the temperature controller 104 further comprises a cooling component. The cooling component is a cooling water pipeline 106. The cooling water pipeline 106 is distributed inside the heating plate 101 and the support 102. As shown in FIG. 1, the cooling water pipe 106 inside the heating plate 101 is stacked on the heating wire 105. Although not shown in the figures, the cooling water line 106 inside the heating plate 101 may also be stacked below the heating wire 105. It can be understood that those skilled in the art would arrange the relative positions and respective arrangement of the heating member and the cooling member in the heating plate 101 and the support 102 according to specific requirements. It will be understood that heating members (such as heating wires 105) and/or cooling members (such as cooling water pipelines 106) may also be provided on the surfaces of the heating plate 101 and the support 102. According to an embodiment of the present disclosure, the temperature controller 104 is a programmable logic controller (PLC). The programmable logic controller 108 is used to control conduction or disconnection to the heating member and/or cooling member according to a control program stored in advance in the programmable logic controller when the monitor 107 monitors that the temperature of the heating plate 101 and the support 102 reach a predetermined temperature. For example, in the process of heating the heating plate 101, when the monitor monitors that the temperature of the heating plate 101 has reached 110° C. (predetermined temperature), the programmable logic controller 108 disconnects (turns off) the heating member, so as to ensure that the temperature of the heating plate 101 is within a temperature range required for the subsequent process. When the monitor monitors that the temperature of the heating plate 101 is significantly higher than the predetermined temperature of the heating plate 101, the programmable logic controller 108 conducts (turns on) the cooling member to lower the temperature of the heating plate 101. The programming logic controller 108 can independently control the heating and cooling members. The temperature controller 104 provided in this embodiment can control the temperature of the heating plate 101 and the support 102, so as to ensure that the temperature difference between the heating plate 101 and the support 102 is as small as possible, thereby increasing the controllability on the temperature. Since the programmable logic controller can modify the control program of the temperature controller 104 at any time, the programmable logic controller provided in this embodiment improves the efficiency of heat curing. It should be noted that the connection in this embodiment may be a physical contact connection (such as electrically connected through a wire), or may be a non-contact connection (such as may be electrically connected through a wireless signal). In the drawings of this embodiment, specific connection structures are not shown, as long as those skilled in the art can achieve the above connection. A person skilled in the art can use a wire or a wireless signal to perform electrical connection, so that the programmable logic controller can control the heating member and/or the cooling member to work, for example, a control of turning on or turning off (conduction or disconnection) the power of the heating member and/or the cooling member, which will not be described here.

FIG. 2 is a schematic view of a support protruding from a heating plate for carrying an object to be cured in an embodiment of the present disclosure. FIG. 3 is a schematic view of a support retracting into a heating plate for placing an object to be cured in an embodiment of the present disclosure. As shown in FIG. 2 and FIG. 3, the support 102 is used to protrude from the heating plate 101 to receive the object to be cured, and the support 102 is also used to retract into the heating plate 101 so as to place the object to be cured on the heating plate 101. The object to be cured comprises a substrate 201 on which an organic layer 202 is disposed. The organic layer 202 comprises a color film material and a pixel isolation material. The color film material forms a color film after a process of heat curing. The pixel isolation material forms a pixel isolation layer after heat curing.

The area corresponding to the heating plate provided in this embodiment is a heating plate area, and the area corresponding to the supporting pin is a supporting pin area. Since the heating plate area and the supporting pin area have substantially the same temperature, the present embodiment provides a heating device that enhancing the evaporation uniformity of the solvent of the film layer, improving the uniformity of the thickness of the film layer after heat curing, reducing the incidence of Pin Mura, and improving product yield and productivity.

Referring to FIG. 3, the temperature of the heating plate ranges from 108° C. to 112° C. Preferably, the temperature of the heating plate is 110° C., the heat curing time of the heating plate is 120 seconds, and the support is heated synchronized with the heating plate. The deposition rate of the RGB trichromatic film material in this embodiment is in the range of 200-250 mm/sec, the exposure energy per unit area is in the range of 70-90 mJ/cm², the formation time is in the range of 80-90 s, and the formation temperature is in the range of 22-24° C.

In this embodiment, an organic layer 202 is provided on the substrate, and the organic layer 202 comprises a color film material and a pixel isolation material. The color film material forms a color film after a process of heat curing, and the pixel isolation material forms a pixel isolation layer after heat curing. The specific process is as follows: coating→heating→exposure→developing→curing, so that a film layer with good uniformity can be formed, which reduces the incidence of Pin Mura.

The present embodiment provides a heating device for heating an OLED substrate, comprising: a heating plate, a support, and a temperature controller, the temperature controller is connected with the heating plate and the support respectively, and the temperature controller is used to synchronously heat the heating plate and the support, so that the temperature of the heating plate and the support are substantially the same; wherein the heating plate comprises an receiving portion for accommodating the support, the support is configured to be able to protrude from the heating plate and retract into the heating plate. The heating plate and the support provided in this embodiment have substantially the same temperature, which improves the temperature difference between the heating plate area and the supporting pin area, improves the evaporation uniformity of solvent of the film layer, and improves the uniformity of the thickness of the film layer after heat curing, reduces the incidence of Pin Mura and improves product yield and productivity.

It can be understood that the above embodiments are merely exemplary embodiments employed to illustrate the principle of the present disclosure, but the present disclosure is not limited thereto. For a person of ordinary skilled in the art, various variations and improvements may be made without departing from the spirit and essence of the present disclosure, and these variations and improvements are also considered to be within the protection scope of the present disclosure.

1-11. (canceled)

12. A heating device for heating an OLED substrate, comprising:
a heating plate,
a support, and
a temperature controller, the temperature controller is connected with the heating plate and the support respectively, and the temperature controller is used to synchronously heat the heating plate and the support, so that the temperature of the heating plate and the support are substantially the same;
wherein the heating plate comprises an receiving portion for accommodating the support, the support is configured to be able to protrude from the heating plate and retract into the heating plate.

13. The heating device according to claim 12, wherein the temperature controller comprises a monitor and a heating member, the heating member configured to heat the heating plate and the support, the monitor is configured to monitor the temperature of the heating plate and the support, the monitor is connected with the heating plate and the support, respectively.

14. The heating device according to claim 13, wherein the temperature controller further comprises a cooling member, and the heating plate and the support are provided with the cooling member.

15. The heating device according to claim 12, wherein the support and the heating plate comprise a heat conductive material.

16. The heating device according to claim 12, wherein the support or the heating plate comprises a heat conductive material.

17. The heating device according to claim 15, wherein the heat conductive material comprises a metal material.

18. The heating device according to claim 16, wherein the heat conductive material comprises a metal material.

19. The heating device according to claim 17, wherein the heat conductive material is stainless steel or aluminum alloy.

20. The heating device according to claim 18, wherein the heat conductive material is stainless steel or aluminum alloy.

21. The heating device according to claim 12, wherein the support is a supporting pin.

22. The heating device according to claim 13, wherein the heating member is a heating wire.

23. The heating device according to claim 22, wherein the heating wire is inside the heating plate and the support.

24. The heating device according to claim 14, wherein the cooling member is a cooling water pipeline.

25. The heating device according to claim 14, wherein the temperature controller further comprises a programmable logic controller, the programmable logic controller is used to control conduction or disconnection to the heating member and cooling member according to a control program stored in advance in the programmable logic controller when the monitor monitors that the temperature of the heating plate and the support reach a predetermined temperature.

26. The heating device according to claim 14, wherein the temperature controller further comprises a programmable logic controller, the programmable logic controller is used to control conduction or disconnection to the heating member or cooling member according to a control program stored in advance in the programmable logic controller when the monitor monitors that the temperature of the heating plate and the support reach a predetermined temperature.
